(19) United States
(12) Patent Application Publication
(10) Pub. No.: US 2024/0105843 A1
(43) Pub. Date: Mar. 28, 2024

(54) TRENCH FIELD-EFFECT TRANSISTOR AND METHOD FOR MANUFACTURING TRENCH FET

(71) Applicant: Hangzhou Silicon-Magic Semiconductor Technology Co., Ltd., Hangzhou City (CN)

(72) Inventors: Jinyong Cai, Hangzhou City (CN); Jian Liu, Hangzhou City (CN); Shida Dong, Hangzhou City (CN); Zhenhan Wang, Hangzhou City (CN)

(73) Assignee: Hangzhou Silicon-Magic Semiconductor Technology Co., Ltd., Hangzhou City (CN)

(21) Appl. No.: 18/475,883

(22) Filed: Sep. 27, 2023

(30) Foreign Application Priority Data
Sep. 27, 2022 (CN) 202211188475.9

(51) Int. Cl. H01L 29/78; H01L 29/423; H01L 29/66

(52) U.S. Cl. CPC H01L 29/7827; H01L 29/4236; H01L 29/66666

(57) ABSTRACT

A method for manufacturing a trench field-effect transistor includes forming an epitaxial layer on a substrate; forming a trench in the epitaxial layer, forming a first insulating layer and a shielding conductor in the trench, where the first insulating layer surrounds the shielding conductor and partially fills the trench; forming a dielectric layer on the epitaxial layer, the first insulating layer, and a side wall of the trench; etching a part of the dielectric layer to form a dielectric region, where the dielectric region is located on the first insulating layer and the side wall of the trench; and forming a second insulating layer and a gate conductor in the trench, where the second insulating layer surrounds the gate conductor, fills the trench, and extends to the surface of the epitaxial layer.

### TECHNICAL FIELD

This application relates to the technical field of semiconductors, and in particular to a trench field-effect transistor (FET) and a method for manufacturing a trench FET.

### BACKGROUND

A metal-oxide-semiconductor field-effect transistor (MOSFET) has many parasitic capacitances. The parasitic capacitances affect an operating speed of the MOSFET. As a size of the MOSFET reduces, a spacing between a gate and a source and a spacing between the gate and a drain also decrease, thereby increasing a capacitance value of the parasitic capacitance. The parasitic capacitances may include a gate-drain capacitance, a gate-source capacitance, and an inter-drain-source capacitance. The gate-drain capacitance slows down a charging/discharging speed and affects performance of the MOSFET.

### SUMMARY

The present application provides a trench field-effect transistor and a method for manufacturing the trench field-effect transistor, which can reduce the gate-drain capacitance and improve the efficiency of the trench field-effect transistor.

The present disclosure provides a method for manufacturing a trench field-effect transistor (FET), comprising: forming an epitaxial layer on a substrate; forming a trench in the epitaxial layer; forming a first insulating layer and a shielding conductor in the trench, wherein the first insulating layer surrounds the shielding conductor; forming a dielectric layer on the epitaxial layer, the first insulating layer, and a side wall of the trench; etching a part of the dielectric layer to form a dielectric region, wherein the dielectric region is located on the first insulating layer and the side wall of the trench; and forming a second insulating layer and a gate conductor in the trench, wherein the second insulating layer surrounds the gate conductor and fills the trench.

The present disclosure provides a trench field-effect transistor (FET), comprising: a substrate; an epitaxial layer, arranged on the substrate; a trench, arranged in the epitaxial layer, wherein the trench extends from a surface of the epitaxial layer into the epitaxial layer; an insulating layer, arranged in the trench; a shielding conductor, arranged in the trench, wherein the shielding conductor is surrounded by the insulating layer and insulated from the epitaxial layer through the insulating layer; a gate conductor, arranged in the trench, wherein the gate conductor is located on the shielding conductor and surrounded by the insulating layer and is insulated from the shielding conductor and the epitaxial layer through the insulating layer; and a dielectric region, arranged between the shielding conductor and the gate conductor and located on a side wall of the trench.

In summary, the trench field-effect transistor and the method for manufacturing the trench field-effect transistor of the present application form a dielectric region between the shielding conductor and the gate conductor, and the dielectric region is located in the trench near the gate conduct, to reduce the value of the gate-drain capacitance and improve the operation of the trench field-effect transistor.

### BRIEF DESCRIPTION OF THE DRAWINGS

FIG. 1 is a cross-sectional view showing a trench field-effect transistor (FET) according to one or more embodiments of this application.

FIG. 2 is a flowchart showing a method for manufacturing a trench FET according to one or more embodiments of this application.

FIG. 3A to FIG. 3G are cross-sectional views showing stages of a method for manufacturing a trench FET according to one or more embodiments of this application.

FIG. 4A to FIG. 4C are flowcharts showing formation of a dielectric region according to one or more embodiments of this application.

FIG. 5 is a cross-sectional view showing a trench FET according to one or more embodiments of this application.

FIG. 6 is a flowchart showing a method for manufacturing a trench FET according to one or more embodiments of this application.

FIG. 7A to FIG. 7F are cross-sectional views showing stages of a method for manufacturing a trench FET according to one or more embodiments of this application.

### DETAILED DESCRIPTION

The terms “first”, “second” and the like in the description, claims, and the drawings of the present disclosure may be used to distinguish similar objects, and are not necessarily used to describe a specific sequence or order. In addition, the terms “comprising” and “including” and any variations thereof, are intended to cover non-exclusive inclusion; for example, processes, methods, systems, products or devices are not limited to the steps or units which are distinctly listed, and may include other steps or units which are not distinctly listed or inherent to these processes, methods, products or devices.

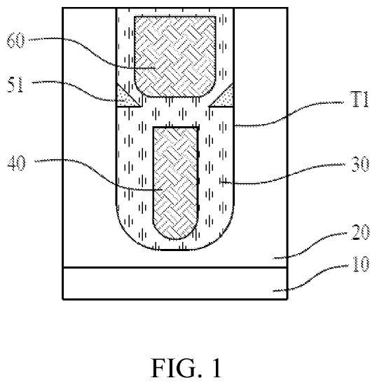

Referring to FIG. 1, FIG. 1 is a cross-sectional view of a trench field-effect transistor (FET) according to one or more embodiments of this application. As shown in FIG. 1, the trench FET includes a substrate 10, an epitaxial layer 20, a trench T1, an insulating layer 30, a shielding conductor 40, a gate conductor 60, and a dielectric region 51.

The epitaxial layer 20 is arranged on the substrate 10. The trench T1 is arranged in the epitaxial layer 20 and extends from a surface of the epitaxial layer 20 to the inside of the epitaxial layer 20. The insulating layer 30 is arranged in the trench T1. The shielding conductor 40 is arranged in the trench T1 and surrounded by the insulating layer 30, and the shielding conductor 40 is insulated from the epitaxial layer 20 through the insulating layer 30. The gate conductor 60 is arranged in the trench T1. Further, the gate conductor 60 is located above the shielding conductor 40 and surrounded by the insulating layer 30, and is insulated from the shielding conductor 40 and the epitaxial layer 20 through the insulating layer 30. The dielectric region 51 is arranged between the shielding conductor 40 and the gate conductor 60 and located on a side wall of the trench T1, and may be a side wall close to the gate conductor 60. In other words, a distance between the dielectric region 51 and the gate conductor 60 is less than a distance between the dielectric region 51 and the shielding conductor 40. The shielding conductor 40, the gate conductor 60, and the dielectric region 51 are covered by the insulating layer 30.

A thickness of the insulating layer 30 between the side wall of the trench T1 and a side wall of the gate conductor 60 is less than a thickness of the insulating layer 30 between the side wall of the trench T1 and a side wall of the shielding conductor 40. A width of the gate conductor 60 projected onto the substrate 10 is greater than a width of the shielding conductor 40 projected onto the substrate 10. A width of the dielectric region 51 projected onto the substrate 10 is less than the width of the gate conductor 60 projected onto the substrate 10.

The substrate 10 and the epitaxial layer 20 have a first dopant type, and materials of the substrate 10 and the epitaxial layer 20 include silicon. The first dopant type is one of an N type and a P type, and a second dopant type is the other of the N type and the P type. In order to form an N-type semiconductor layer or region, an N-type dopant may be implanted in the substrate 10 and the epitaxial layer 20, and the N-type dopant may be, for example, phosphorus (P) and arsenic (As). In order to form a P-type semiconductor layer or region, a P-type dopant may be doped in the substrate 10 and the epitaxial layer 20. The P-type dopant is, for example, boron (B). In an embodiment, the substrate 10 and the epitaxial layer 20 are of an N type.

The material of the insulating layer 30 can be silicon oxide (SiOx), silicon nitride (SiNx), silicon oxynitride (SiON), silicon carbonitride (SiCN), silicon oxycarbide (SiOC), aluminum oxide (AlOx), Hafnium (HfO2) or a composition thereof. The material of dielectric region 51 can be low dielectric constant material, and the dielectric constant of low dielectric constant material is less than 3.9. The low dielectric constant material can comprise polyimide (Polyimide, PI), hydrogen silsesquioxane (hydrogen silsesquioxane, HSQ) or methyl silsesquioxane (methylsilsesquioxane, MSQ). The material of the shielding conductor 40 and the gate conductor 60 may include metal material, doped polysilicon or a combination thereof, and the metal material may include indium (In), tin (Sn), aluminum (Al), gold (Au), platinum (Pt), indium (In), zinc (Zn), germanium (Ge), silver (Ag), lead (Pb), palladium (Pd), copper (Cu), beryllium gold (AuBe), beryllium germanium (BeGe), nickel (Ni), lead tin (PbSn), chromium (Cr), gold zinc (AuZn), titanium (Ti), tungsten (W) or titanium tungsten (TiW).

In this embodiment, two or more dielectric regions 51 may be arranged. When a plurality of dielectric regions 51 are arranged, the dielectric regions 51 may be arranged on the side walls of the trench on two opposite sides of the gate conductor 60 by using a center line of the gate conductor 60 as a reference. In an embodiment, when an even number of dielectric regions 51 are arranged, the dielectric regions 51 may be symmetrical with respect to the center line of the gate conductor 60 as an axis of symmetry. Since the dielectric region 51 is located between the shielding conductor 40 and the gate conductor 60 and made of a low dielectric constant material, a gate-drain capacitance can be reduced by increasing a dielectric thickness on a bottom of the gate conductor 60 (that is, thicknesses of the insulating layer 30 and the dielectric region 51) and decreasing a dielectric constant.

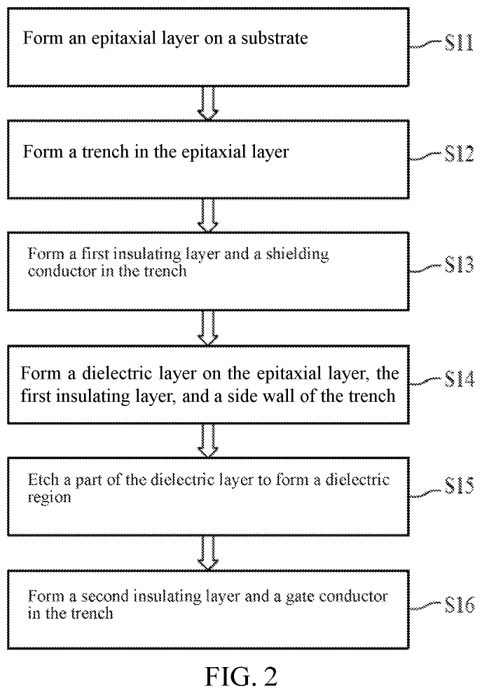

Referring to FIG. 2, FIG. 2 is a flowchart showing a method for manufacturing a trench FET according to one or more embodiments of this application. As shown in FIG. 2, the method for manufacturing a trench FET includes step S11 to step S16.

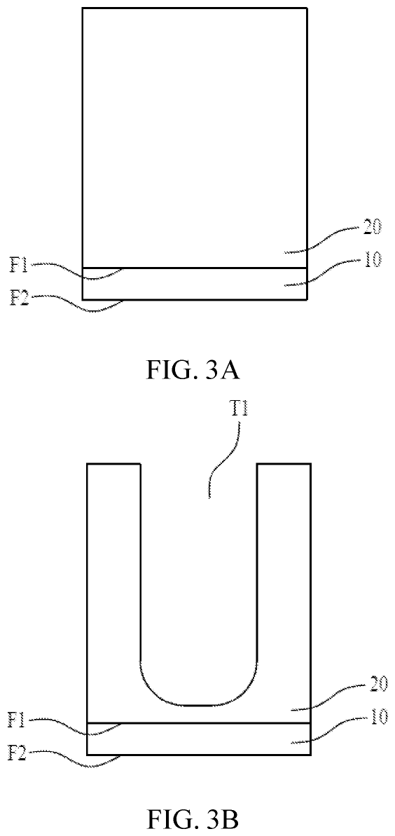

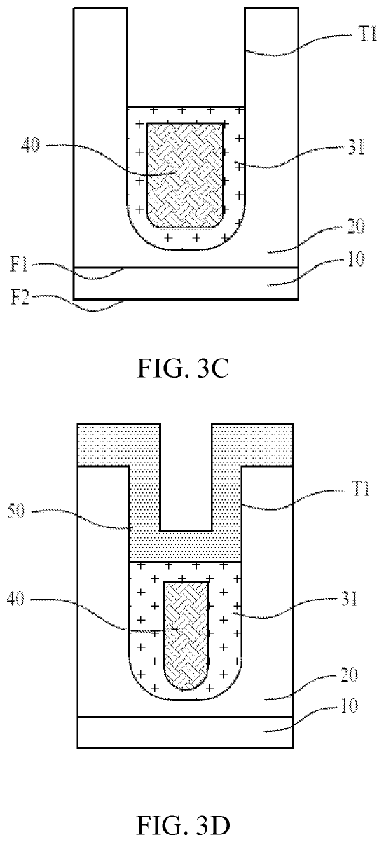

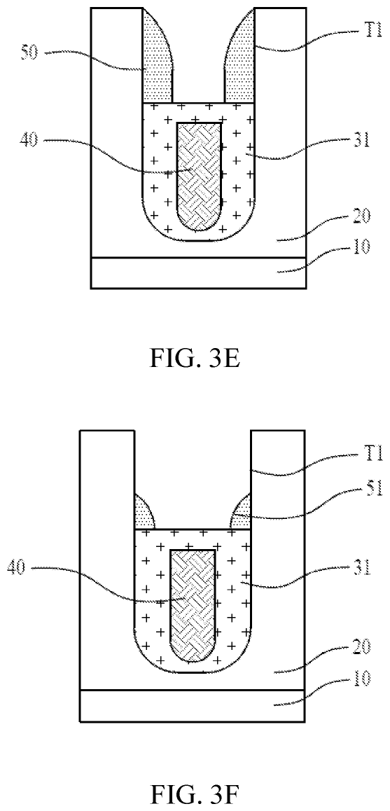

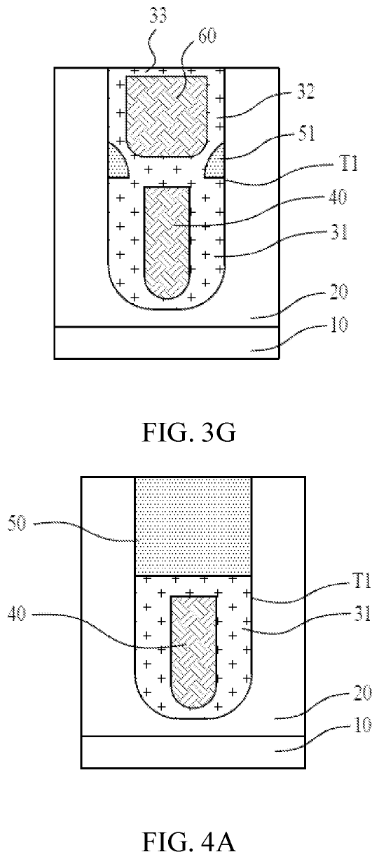

Step S11: Form an epitaxial layer 20 on a substrate 10. As shown in FIG. 3A, the substrate 10 includes a first surface F1 and a second surface F2, the epitaxial layer 20 is formed on the first surface F1 of the substrate 10, and a doping concentration of the epitaxial layer 20 is less than a doping concentration of the substrate 10.

The method for forming the epitaxial layer 20 may be chemical vapor deposition (chemical vapor deposition, CVD), molecular beam epitaxy (molecular beam epitaxy, MBE) or atomic layer deposition (atomic layer deposition, ALD) or the formation of the epitaxial layer 20 which can be other methods for forming a film layer, which is not limited herein.

Step S12: Form a trench T1 in the epitaxial layer 20. As shown in FIG. 3B, the trench T1 extends from the surface of the epitaxial layer 20 toward the substrate 10 and ends in the epitaxial layer 20.

In an embodiment, etching may be performed from the surface of the epitaxial layer 20 to the inside of the epitaxial layer 20 through laser etching by using a patterned photoresist layer, and the trench T1 is formed in the epitaxial layer 20. For example, a depth of the trench T1 and an opening width of the trench T1 are controlled by adjusting laser energy, a spot size, and an etching time.

In an embodiment, an oxide layer is formed on the epitaxial layer 20, and then the patterned photoresist layer is formed on the oxide layer, etched from the opening of the photoresist layer to the oxide layer, and stopped on the surface of epitaxial layer 20. Further, a through opening is formed on the oxide layer. The oxide layer having an opening is used as a hard mask and is etched into the epitaxial layer 20 from the surface of the epitaxial layer 20, and the trench T1 is formed in the epitaxial layer 20. The etching may be inductively coupled plasma reactive-ion etching (ICP-RIE) or wet etching, and the depth of the trench T1 and the opening width of the trench T1 may be controlled by adjusting the etching solution concentration and the etching time.

Step S13: Form a first insulating layer 31 and a shielding conductor 40 in the trench T1, where the first insulating layer 31 surrounds the shielding conductor 40.

As shown in FIG. 3C, the first insulating layer 31 is formed on the bottom and a part of a side wall of the trench T1, the first insulating layer 31 does not fill the entire trench T1, the shielding conductor 40 is formed on the first insulating layer 31 on the bottom of the trench T1, and the first insulating layer 31 surrounds the shielding conductor 40.

The first insulating layer 31 is formed on the bottom and the side wall of the trench T1 and the surface of the epitaxial layer 20 through chemical vapor deposition or a thermal oxidation process. The material of the first insulating layer 31 may include silicon oxide (SiOx), silicon nitride (SiNx), silicon oxynitride (SiON), silicon carbonitride (SiCN), silicon oxycarbide (SiOC), aluminum oxide (AlOx), Hafnium dioxide (HfO2) or combinations thereof. Through the chemical vapor deposition, a conductor layer is formed inside the trench T1 and on the surface of the epitaxial layer 20 to fill the trench T1, and the conductor layer on the surface of the epitaxial layer 20 and inside the trench T1 is partially etched, to form a part of the conductor layer shown in FIG. 3C as the shielding conductor 40. The part of the conductor layer may be etched through an isotropic ion or a non-isotropic ion.

The photoresist layer is formed on the shielding conductor 40, so that the photoresist layer fills the trench T1. Then a part of the first insulating layer 31 located on the epitaxial layer 20 and a part of the first insulating layer 31 located on two opposite side walls of the trench T1 are etched, and a part of the first insulating layer 31 located on the side wall of the trench T1 as shown in FIG. 3C is formed, so as to expose the epitaxial layer 20 and the part of the side wall of the trench T1 and remove the photoresist layer. The first insulating layer 31 is formed again, so that the first insulating layer 31 covers the shielding conductor 40. That is to say, the first insulating layer 31 surrounds the shielding conductor 40.

Step S14: Form a dielectric layer 50 on the epitaxial layer 20, the first insulating layer 31, and the side wall of the trench T1.

As shown in FIG. 3D, the dielectric layer 50 is formed on the epitaxial layer 20, the first insulating layer 31, and the side wall of the trench T1 without the first insulating layer 31. The method of forming the dielectric layer 50 may be chemical vapor deposition (CVD), molecular beam epitaxy (MBE), atomic layer deposition (atomic layer deposition, ALD) or sputtering.

Step S15: Etch a part of the dielectric layer 50 to form a dielectric region 51, where the dielectric region 51 is located on the first insulating layer 31 and the side wall of the trench T1.

As shown in FIG. 3E, a part of the dielectric layer 50 on the epitaxial layer 20, the first insulating layer 31, and the side wall of the trench T1 is etched through reactive ions, to form the dielectric layers 50 located on two side walls of the trench T1. The dielectric layers 50 on the two side walls are not connected to each other. In this case, a thickness of the dielectric layer 50 located on the side wall of the trench T1 is less than a thickness of the dielectric layer 50 located on the side wall of the trench T1 as shown in FIG. 3D.

As shown in FIG. 3F, gas flow and a reaction time of the reactive ion gas are adjusted, and a part of the dielectric layers 50 located on two side walls of the trench T1 is etched again through the reactive ions, to form the dielectric layers 50 located on the first insulating layer 31 and the side walls of the trench T1 as two dielectric regions 51. Each of the dielectric region 51 covers a part of the first insulating layer 31 and a part side wall of the trench T1, and a spacing is formed between the two dielectric regions 51.

Step S16: Form a second insulating layer 32 and a gate conductor 60 in the trench T1, where the second insulating layer 32 surrounds the gate conductor 60.

As shown in FIG. 3G, the second insulating layer 32 is formed on the part of the side wall of the trench T1 and the shielding conductor 40, the gate conductor 60 is formed in the trench T1 having the second insulating layer 32, and a third insulating layer 33 is formed to cover the gate conductor 60.

The second insulating layer 32 is formed on the part of the side wall of the trench T1, the first insulating layer 31 and on the surface of the epitaxial layer 20 through the chemical vapor deposition or the thermal oxidation process. The material of the second insulating layer 32 may include silicon oxide (SiOx), silicon nitride (SiNx), silicon oxynitride (SiON), silicon carbonitride (SiCN), silicon oxycarbide (SiOC), aluminum oxide (AlOx), Hafnium dioxide (HfO2) or combinations thereof. The conductor layer is formed inside the trench T1 and on the surface of the epitaxial layer 20 through the chemical vapor deposition, to fill the trench T1, and a part of the conductor layer on the surface of the epitaxial layer 20 and inside the trench T1 is etched, to form a part of the conductor layer shown in FIG. 3G as the gate conductor 60. The part of the conductor layer may be etched through the reactive ions.

Then the third insulating layer 33 is formed again, so that the third insulating layer 33 covers the gate conductor 60, and a part of the third insulating layer 33 is etched so that the surface of the third insulating layer 33 is flush with the surface of the epitaxial layer 20.

The insulating layer 30 is jointly formed by the first insulating layer 31, the second insulating layer 32, and the third insulating layer 33. Materials of the first insulating layer 31, the second insulating layer 32, and the third insulating layer 33 may be the same or different from each other, without limiting the composition and configuration of the first insulating layer 31, the second insulating layer 32, and the third insulating layer 33. A thickness of the first insulating layer 31 on the side wall of the trench T1 is greater than a thickness of the second insulating layer 32 on the side wall of the trench T1.

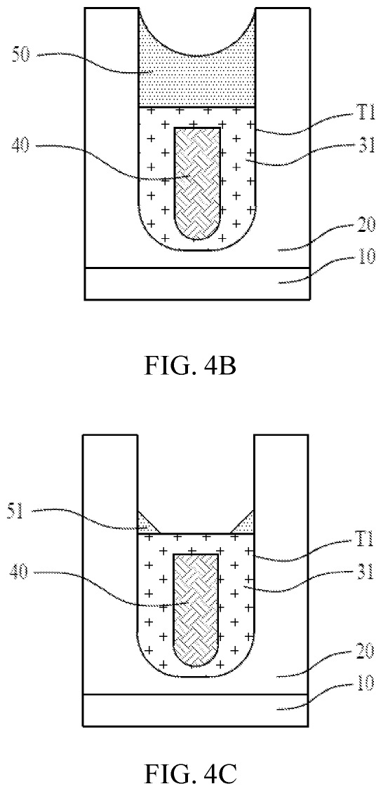

Referring to FIG. 4A to FIG. 4C, FIG. 4A to FIG. 4C are flowcharts showing formation of a dielectric region according to one or more embodiments of this application. FIG. 4A corresponds to step S14 shown in FIG. 2, and FIG. 4B and FIG. 4C correspond to step S15 shown in FIG. 2.

As shown in FIG. 4A, a dielectric layer 50 is formed in a trench T1 and on an epitaxial layer 20, and then planarized through chemical mechanical polishing. As shown in FIG. 4B, a part of the dielectric layer 50 on the first insulating layer 31 in the trench T1 is etched through wet etching. As shown in FIG. 4C, an etching solution concentration and an etching time for the wet etching are adjusted, and a part of the dielectric layer 50 located in the trench T1 is etched again through the wet etching, to form the dielectric layer 50 located on the first insulating layer 31 and at a junction of the two side walls of the trench T1 as two dielectric regions 51. Each of the dielectric regions 51 is a side wall covering a part of the first insulating layer 31 and a part of the trench T1.

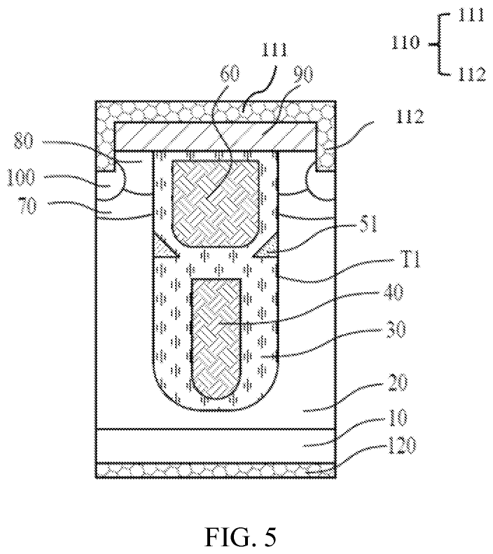

Referring to FIG. 5, FIG. 5 is a cross-sectional view showing a trench FET according to one or more embodiments of this application. As shown in FIG. 5, the trench FET includes a substrate 10, an epitaxial layer 20, a trench T1, an insulating layer 30, a shielding conductor 40, a gate conductor 60, a dielectric region 51, a well region 70, a source region 80, an interlayer dielectric layer 90, a body contact region 100, a conductive channel, a metal region 110, and a drain metal layer 120. The configuration of the substrate 10, the epitaxial layer 20, the trench T1, the insulating layer 30, the shielding conductor 40, the gate conductor 60, and the dielectric region 51 is the same as that of the one or more embodiments shown in FIG. 1, and the details are not described herein again.

The well region 70 is arranged in the epitaxial layer 20 and adjacent to the trench T1. The well region 70 has a second dopant type. The source region 80 is arranged above the well region 70 and adjacent to the trench T1. The source region 80 has a first dopant type. The body contact region 100 is arranged in the well region 70 and adjacent to the source region 80. The body contact region 100 has the second dopant type.

The interlayer dielectric layer 90 is arranged on the source region 80 and located on the gate conductor 60 and covers an opening of the trench T1. In other words, the interlayer dielectric layer 90 is located on the epitaxial layer 20. The conductive channel extends through the interlayer dielectric layer 90 and the source region 80 and extends to the body contact region 100. A metal region 110 includes a source metal layer 111 and two conductive channels 112. The source metal layer 111 is arranged on the interlayer dielectric layer 90, and the two conductive channels 112 are located on two opposite sides of the interlayer dielectric layer 90. The source metal layer is electrically connected to the body contact region 100 through the conductive channel. The drain metal layer 120 is arranged on a second surface F2 of the substrate 10.

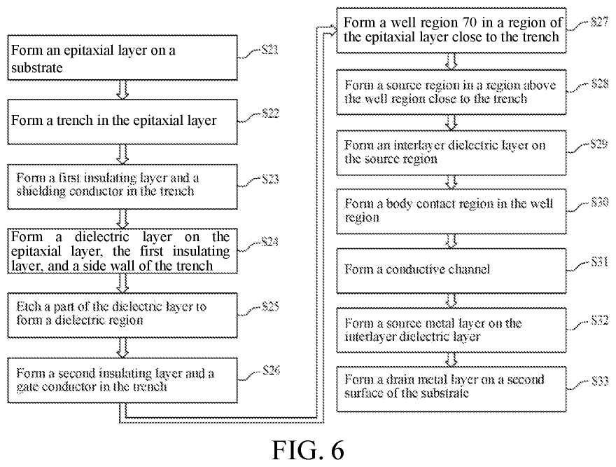

Referring to FIG. 6, FIG. 6 is a flowchart showing a method for manufacturing a trench FET according to one or more embodiments of this application. As shown in FIG. 6, the method for manufacturing a trench FET includes step S21 to step S33. Step S21 to step S26 are the same as step S11 to step S16 shown in FIG. 2, and the details are not described herein again. A trench FET 1B shown in FIG. 5 may be manufactured by using the method for manufacturing a trench FET shown in FIG. 6, which is not limited thereto. The manufacturing of the trench FET 1B shown in FIG. 5 by using the method for manufacturing a trench FET shown in FIG. 6 is described below by using examples.

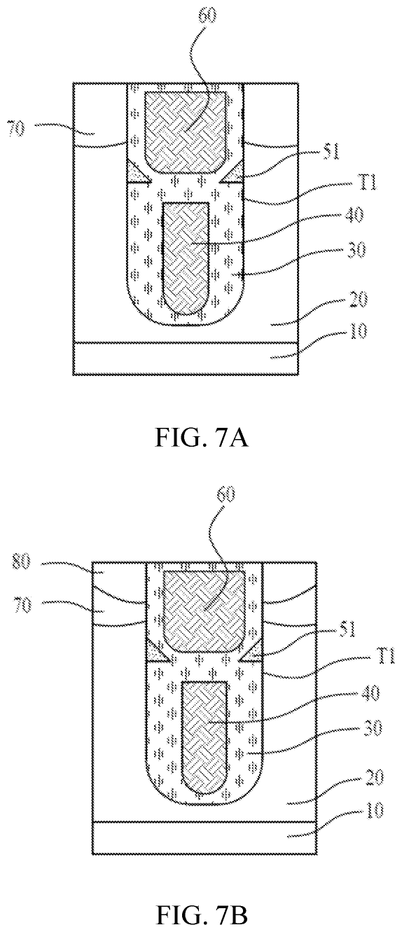

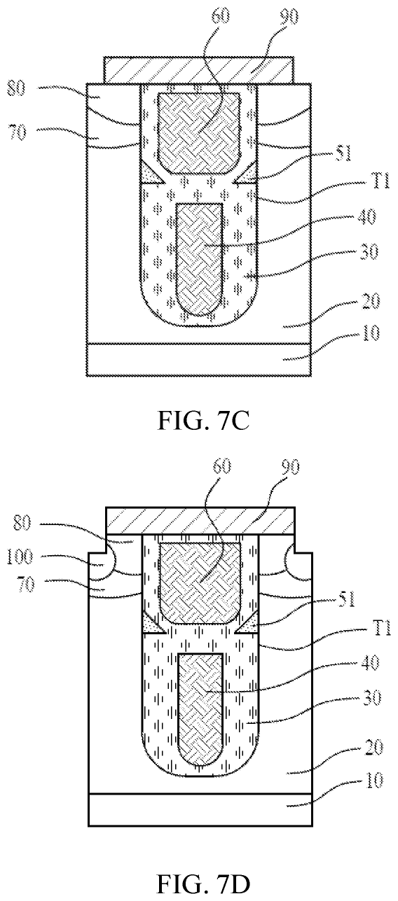

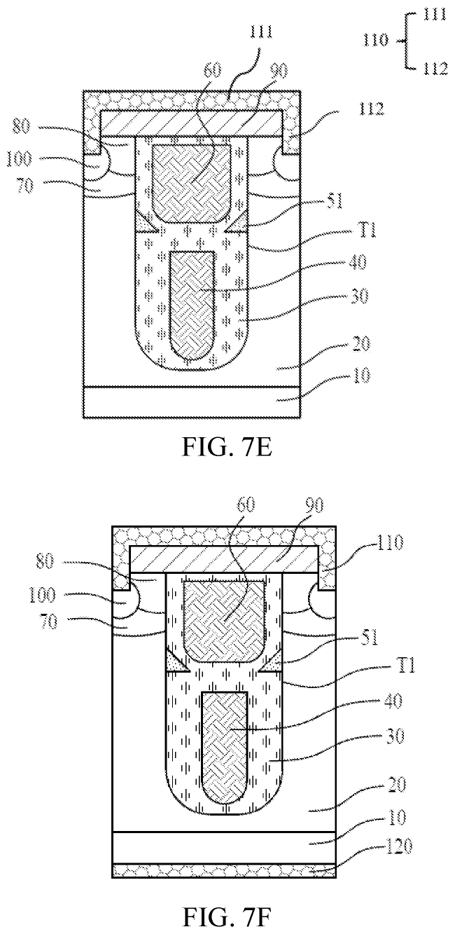

Step S27: Form a well region 70 in a region of the epitaxial layer 20 close to the trench T1. Specifically, as shown in FIG. 7A, two well regions 70 are formed on the epitaxial layer 20 through the ion implantation technique by using the trench T1 as a reference. The two well regions 70 correspond to each other and are in the region close to the trench T1.

Step S28: Form a source region 80 in a region above the well region 70 close to the trench T1.

As shown in FIG. 7B, two source regions 80 are formed in two well regions 70 through the ion implantation technique, so that the two source regions 80 are located above the well regions 70 and in the region close to the trench T1.

Step S29: Form an interlayer dielectric layer 90 on the source region 80.

As shown in FIG. 7C, the interlayer dielectric layer 90 is formed to cover the opening of the trench T1 and the two source regions 80 through chemical vapor deposition, and a part of the interlayer dielectric layer 90 is etched to expose a part of the source region 80. The material of the interlayer dielectric layer 90 may include silicon oxide (SiOx), silicon nitride (SiNx), silicon oxynitride (SiON), silicon carbonitride (SiCN), silicon oxycarbide (SiOC), aluminum oxide (AlOx), Hafnium dioxide (HfO2) or combinations thereof.

Step S30: Form a body contact region 100 in the well region 70.

As shown in FIG. 7D, two body contact regions 100 are formed in two well regions 70 through the ion implantation technique, so that the well region 70, the source region 80, and the body contact region 100 are adjacent to each other.

Sizes of the well region 70, the source region 80, and the body contact region 100 shown in FIG. 7A, FIG. 7B, and FIG. 7D are merely for illustration. A depth and a doping concentration required by the well region 70, the source region 80, and the body contact region 100 can be realized by controlling parameters for the ion implantation, for example, implantation energy and dosage. In addition, an additional photoresist mask may also be used, so as to control transverse extended regions of the body contact region 100 and the source region 80.

Step S31: Form a conductive channel 112, where the conductive channel 112 extends through the interlayer dielectric layer 90 and the source region 80 and extends to the body contact region 100. A part of the interlayer dielectric layer 90 and the source region 80 are etched to form the conductive channel 112 that extends through the interlayer dielectric layer 90 and the source region 80 and reaches the body contact region 100.

Step S32: Form a source metal layer 111 on the interlayer dielectric layer 90, where the source metal layer 111 is electrically connected to the body contact region 100 through the conductive channel 112. As shown in FIG. 7E, the source metal layer 111 is formed on the interlayer dielectric layer 90 through sputtering or evaporation to contact the conductive channel 112, so that the source metal layer is electrically connected to the body contact region 100 through the conductive channel 112.

Step S33: Form a drain metal layer 120 on the second surface F2.

As shown in FIG. 7F, the drain metal layer 120 is formed on the second surface F2 of the substrate 10 through sputtering or evaporation.

In step S32 to step S33, the material of the metal region 110 and the drain metal layer 120 may be indium (In), tin (Sn), aluminum (Al), gold (Au), platinum (Pt), indium (In), zinc (Zn), germanium (Ge), silver (Ag), lead (Pb), palladium (Pd), copper (Cu), beryllium gold (AuBe), beryllium germanium (BeGe), nickel (Ni), lead tin (PbSn), chromium (Cr), gold zinc (AuZn), titanium (Ti), tungsten (W) or titanium tungsten (TiW).

In summary, the trench field-effect transistor and the method for manufacturing the trench field-effect transistor of the present application form a dielectric region between the shielding conductor and the gate conductor, and the dielectric region is located in the trench near the gate conduct, to reduce the value of the gate-drain capacitance and improve the operation of the trench field-effect transistor.

What is claimed is:

1. A method for manufacturing a trench field-effect transistor (FET), comprising:
forming an epitaxial layer on a substrate;
forming a trench in the epitaxial layer;
forming a first insulating layer and a shielding conductor in the trench, wherein the first insulating layer surrounds the shielding conductor;
forming a dielectric layer on the epitaxial layer, the first insulating layer, and a side wall of the trench;
etching a part of the dielectric layer to form a dielectric region, wherein the dielectric region is located on the first insulating layer and the side wall of the trench; and
forming a second insulating layer and a gate conductor in the trench, wherein the second insulating layer surrounds the gate conductor and fills the trench.

2. The method for manufacturing a trench FET according to claim 1, wherein the etching a part of the dielectric layer to form a dielectric region further comprises: forming a plurality of dielectric regions on the side wall of the trench, wherein a spacing is formed between two adjacent dielectric regions.

3. The method for manufacturing a trench FET according to claim 1, wherein the dielectric region is located between the shielding conductor and the gate conductor, and a distance between the dielectric region and the gate conductor is less than a distance between the dielectric region and the shielding conductor.

4. The method for manufacturing a trench FET according to claim 1, wherein the etching a part of the dielectric layer to form a dielectric region comprises:
etching a part of the dielectric layer located on the epitaxial layer, the first insulating layer, and the side wall of the trench through reactive ions, to form the dielectric layers respectively located on two opposite side walls of the trench, wherein the dielectric layers on the two opposite side walls of the trench are not connected to each other;
adjusting gas flow and a reaction time of a reactive ion gas, and etching a part of the dielectric layers located on the two opposite side walls of the trench again through the reactive ions; and
forming two dielectric regions respectively located on the first insulating layer and the two opposite side walls of the trench.

5. The method for manufacturing a trench FET according to claim 1, wherein the etching a part of the dielectric layer to form a dielectric region further comprises:
etching the dielectric layer on the epitaxial layer and a part of the dielectric layer in the trench through wet etching;
adjusting an etching solution concentration and an etching time for the wet etching, and etching the part of the dielectric layer located in the trench again through the wet etching; and
forming two dielectric regions respectively located on the first insulating layer and two opposite side walls of the trench.

6. A trench field-effect transistor (FET), comprising:
a substrate;
an epitaxial layer, arranged on the substrate;
a trench, arranged in the epitaxial layer, wherein the trench extends from a surface of the epitaxial layer into the epitaxial layer;
an insulating layer, arranged in the trench;
a shielding conductor, arranged in the trench, wherein the shielding conductor is surrounded by the insulating layer and insulated from the epitaxial layer through the insulating layer;
a gate conductor, arranged in the trench, wherein the gate conductor is located on the shielding conductor and surrounded by the insulating layer and is insulated from the shielding conductor and the epitaxial layer through the insulating layer; and
a dielectric region, arranged between the shielding conductor and the gate conductor and located on a side wall of the trench.

7. The trench FET according to claim 6, wherein a distance between the dielectric region and the gate conductor is less than a distance between the dielectric region and the shielding conductor.

8. The trench FET according to claim 6, wherein a thickness of the insulating layer between the side wall of the trench and a side wall of the gate conductor is less than a thickness of the insulating layer between the side wall of the trench and a side wall of the shielding conductor.

9. The trench FET according to claim 6, wherein a plurality of dielectric regions are arranged, each of the dielectric regions is made of a low dielectric constant material, and a dielectric constant of the low dielectric constant material is less than 3.9.

10. The trench FET according to claim 6, wherein a plurality of dielectric regions are arranged, and when an even number of dielectric regions are arranged, the dielectric regions are symmetrical with respect to a center line of the gate conductor as an axis of symmetry.
